(19) United States
(12) Patent Application Publication
(10) Pub. No.: US 2026/0051426 A1
(43) Pub. Date: Feb. 19, 2026

(54) ELECTRICAL SYSTEM OF AN ELECTRIC PROPULSION UNIT OF AN AIRCRAFT

(71) Applicant: SAFRAN ELECTRICAL & POWER, BLAGNAC (FR)

(72) Inventors: Vincent CHAPERON, MOISSY-CRAMAYEL (FR); Samir NEHME, MOISSY-CRAMAYEL (FR); Eric GUILLARD, MOISSY-CRAMAYEL (FR)

(73) Assignee: SAFRAN ELECTRICAL & POWER, BLAGNAC (FR)

(21) Appl. No.: 19/101,940

(22) PCT Filed: Aug. 4, 2023
(86) PCT No.: PCT/FR2023/051241

§ 371 Date: Feb. 7, 2025

(30) Foreign Application Priority Data
Aug. 11, 2022 (FR) 2208258

(51) Int. Cl. B64D 27/35; H01B 17/14

(52) U.S. Cl. CPC H01B 17/14

(57) ABSTRACT

An electrical system having an electric circuit having a electrically insulating flat support and two electric conductors secured to the flat support, the two electric conductors being configured to have different respective electric potentials during operation of the electric circuit, the two electric conductors being separated from one another by an air insulation distance and an electrically insulating spacer extending over the flat support between the two electric conductors, and having raised elements, defining a leakage path between the two electric conductors along the spacer, where the leakage path passes via the raised elements.

### TECHNICAL FIELD OF THE INVENTION

The present invention relates to an electrical system of an electric propulsion unit of an aircraft, as well as an electric propulsion unit with such an electrical system and an aircraft with such an electric propulsion unit. The invention also relates to a method of manufacturing an electrical system of a propulsion unit of an aircraft.

### TECHNICAL BACKGROUND

The electric propulsion or hybrid aircrafts (electric propulsion and thermal propulsion), whether with vertical take-off and landing (VTOL), short take-off and landing (STOL) or conventional take-off and landing (CTOL), constitute a very promising future market, with significant prospects and demand for intra- and inter-urban transport of both goods and people. The electric propulsion unit of these aircrafts is thus achieved at least in part by one or more electric motors, the number varying according to the architecture of the aircrafts.

These electric propulsion units use electric circuits with ever higher voltage levels, which poses the problem of partial discharges at altitude. In fact, partial discharges can first appear in the air between two electric conductors at different potentials, when the distance in air between these two conductors is not sufficient, i.e. less than a minimum insulation distance. Partial discharges can also occur on the material, along one or more electrically insulating pieces extending between the two electric conductors. The two parts must therefore be separated from each other, along a leakage path on the insulating part(s), by more than a minimum leakage distance. The minimum leakage distance along the material is greater than the minimum air insulation distance, in a ratio that increases with altitude, for example because of the reduction in oxygen levels with altitude.

In addition, the search for weight savings is driving the search for solutions that bring the components closer together. In the case of an electronic board with electric conductors carrying the positive and negative potential respectively of a DC supply voltage (which can reach several hundred volts), compliance with the air insulation distance and the leakage distance on the material imposes severe constraints on the routing in the electronic board.

It may therefore be desirable to provide an electrical system for an aircraft propulsion unit, which enables at least some of the above-mentioned problems and constraints to be overcome.

### SUMMARY OF THE INVENTION

An electrical system of an electric propulsion unit of an aircraft is therefore proposed, characterised in that it comprises:
an electric circuit comprising an electrically insulating flat support and two electric conductors secured to the flat support, the two electric conductors being designed to have different respective electric potentials during operation of the electric circuit, the two electric conductors being separated from each other by an air insulation distance; and
an electrically insulating spacer extending over the flat support, between the two electric conductors, and having reliefs so as to define a leakage path between the two electric conductors along the spacer, this leakage path passing through the reliefs.

In this way, by passing through the reliefs, the leakage path is no longer straight but “compressed”, which means that the electric conductors can be brought closer together, as long as the air insulation distance is sufficient. In other words, the reliefs of the part increase the length of the leakage path, with the same air insulation distance, so that the two electric conductors can be brought closer together without the risk of partial discharges. In addition, the use of a spacer allows the reliefs of the electrically insulating flat support to be avoided. In fact, machining the electrically insulating flat support can be complex and costly, for example when it is a printed circuit board. Furthermore, it can be complicated to modify the insulating flat support in the event of an error, or when the environment of the electrical system changes, for example when the aircraft's operating altitude is changed, or when the electronic system is modified so that the potential difference is higher, or when the pollution and/or humidity level is different from that envisaged, etc. On the other hand, it is easy to change the spacer, replacing it with a new spacer more suited to the new environment.

The invention may also comprise one or more of the following optional characteristics, in any technically possible combination.

Preferably, the spacer is made of at least one of: Polyarylamide, Polyamide 6-6, Polusulfone, and Polyetheretherketone.

Also preferably, the reliefs comprise at least one groove.

Also preferably, the groove has a rectangular cross-sectional profile.

Also preferably, the groove has a trapezoidal cross-sectional profile.

Also preferably, the groove has a width equal to at least 20% of a length of a minimum leakage path to avoid partial discharges between the two electric conductors on the spacer.

Also preferably, the groove has a height equal to at least 25% of a length of a minimum leakage path to avoid partial discharges between the two electric conductors on the spacer.

An electric propulsion unit of an aircraft comprising an electrical system according to the invention is also proposed.

An aircraft comprising an electric propulsion unit according to the invention is also proposed.

Also proposed is a method of manufacturing an electrical system of an electric propulsion unit of an aircraft, comprising:
obtaining an electric circuit having an electrically insulating flat support and two electric conductors secured to the flat support, the two electric conductors being designed to have different respective electric potentials in operation of the electric circuit, the two electric conductors being separated from one another by an air insulation distance; the method further comprising:
adding an electrically insulating spacer, so as to extend over the flat support, between the two electric conductors, the spacer having reliefs so as to define a leakage path between the two electric conductors along the spacer, this leakage path passing through the reliefs.

Preferably, the method comprises:
calculating a minimum insulation distance between the two electric conductors, for example as a function of at least one of: a maximum potential difference between the two electric conductors during operation of the electric circuit, at a maximum altitude that the aircraft is designed to reach, at a maximum level of pollution that the aircraft is designed to pass through and at the maximum level of humidity that the aircraft is designed to pass through, the electric circuit being obtained with the two electric conductors spaced apart by the air insulation distance, the latter being greater than or equal to the minimum insulation distance;
calculating a length of a minimum leakage path from the maximum altitude that the aircraft is designed to reach, for example from the minimum insulation distance and a coefficient varying with altitude by which the minimum insulation distance must be multiplied to obtain the length of the minimum leakage path; and
designing the reliefs of the spacer so that the leakage path has a length greater than or equal to the length of the minimum leakage path.

### BRIEF DESCRIPTION OF THE FIGURES

The invention will be better understood with the aid of the following description, given only by way of example and made with reference to the attached drawings wherein:
FIG. 1 is a top view of an electronic board, according to the invention, of an electrical system of an electric propulsion unit of an aircraft, with a spacer between two electric conductors,

FIG. 2 is a cross-sectional view of a first embodiment of a groove in the spacer,

FIG. 3 is a cross-sectional view of a second embodiment of a groove in the spacer,

FIG. 4 is a cross-sectional view of two grooves in the second embodiment,

FIG. 5 is a similar view to FIG. 1, without using the spacer, and

FIG. 6 is a block diagram illustrating the steps in a method according to the invention for installing an electrical insulation.

### DETAILED DESCRIPTION OF THE INVENTION

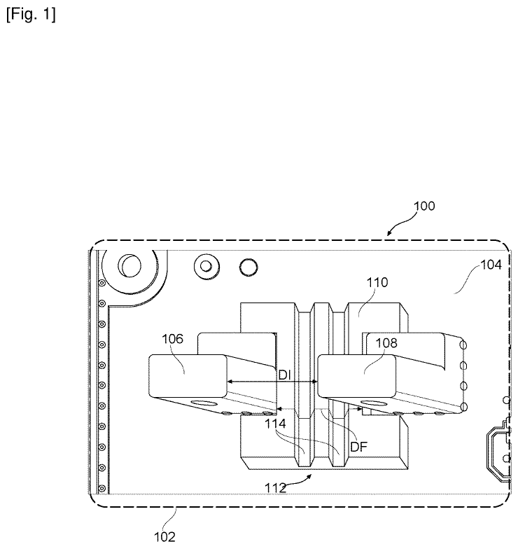

With reference to FIG. 1, an example of an electrical system 100 of a propulsion unit of an aircraft, according to the invention, will now be described.

The electrical system 100 firstly comprises an electric circuit 102 comprising an electrically insulating flat support 104, for example a printed circuit board.

The electrical system 100 also comprises two electric conductors 106, 108 secured to the flat support 104 designed to present two different respective electric potentials during operation of the electric circuit 102. These are, for example, electrical terminals designed to be respectively connected to respective busbars and to respectively present a positive potential and a negative potential of a DC supply voltage, for example greater than 100 V. Alternatively, the electric conductors 106, 108 could be busbars, for example for transporting the DC supply voltage, studs, contactors, or even measurement probes.

The two electric conductors 106, 108 are separated from each other by an air insulation distance DI. The insulation distance DI is, by definition, the shortest straight line distance in air between the two conductors 106, 108.

To avoid partial discharges through the air, the insulation distance DI must be greater than a minimum insulation distance DIₘᵢₙ previously calculated for example as a function of at least one of: the maximum potential difference between the two operating conductors of the electric circuit, at the maximum altitude that the aircraft is designed to reach, at the maximum level of pollution and at the maximum level of humidity that the aircraft is designed to pass through. Generally, the electric conductors 106, 108 so that the insulation distance DI is equal to the minimum insulation distance DIₘᵢₙ.

The electrical system 100 also includes an electrically insulating spacer 110 extending over the flat support 104, between the two electric conductors 106, 108. The spacer 110 has reliefs 112 so as to define a leakage path LF between the two electric conductors 106, 108 along the spacer 110, this leakage path LF passing through the reliefs 112. The leakage path LF is, by definition, the shortest distance running on the spacer 110 between the two conductors 106, 108.

To avoid partial discharges along the spacer 110, the leakage path LF has a length which must be greater than the length of a minimum leakage path LFₘᵢₙ equal to the insulation distance multiplied by a coefficient (greater than 1), this coefficient increasing with altitude. In this way, the coefficient corresponding to the altitude that the aircraft is designed to reach is used to calculate the length of the minimum leakage path LFₘᵢₙ.

The reliefs 112 are thus designed so that the length of the leakage path LF is equal to or greater than the length of the minimum leakage path LFₘᵢn, preferably equal.

For example, the reliefs 112 comprise at least one groove 114 (two in the example shown), for example rectilinear and perpendicular to the leakage path LF.

The spacer is made, for example, of at least one of: Polyarylamide (often referred to as PAA), Polyamide 6-6 (often abbreviated to PA66), Polusulfone (often referred to as PSU), and Polyetheretherketone (often referred to as PEEK GLx, x ranging from 1 to 30).

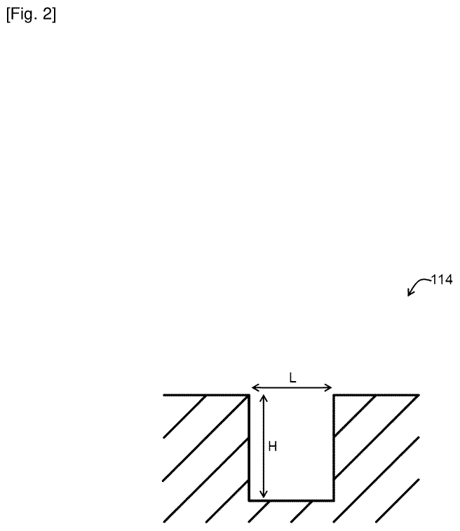

With reference to FIG. 2, each groove 114 may have a rectangular cross-sectional profile. Preferably, in accordance with standard EN60664-1 “isolation_système_basse_tension”, the groove 114 has a width L equal to at least 20% of the length of the minimum leakage path LFₘᵢₙ and/or a height H equal to at least 25% of the length of the minimum leakage path LFₘᵢₙ.

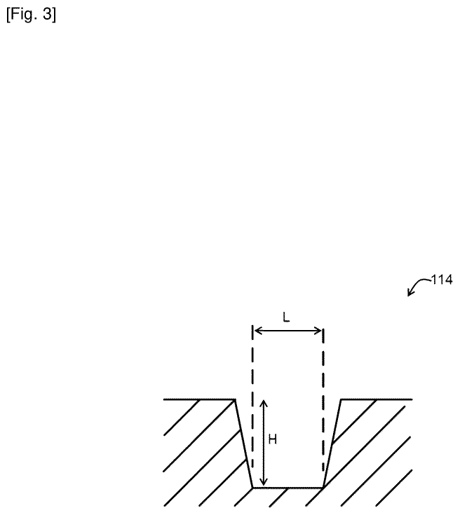

With reference to FIG. 3, each groove 114 can also have a trapezoidal cross-sectional profile. Preferably, as before, the groove 114 has a width L (dimension of the base of the trapezium, at the bottom of the groove 114) equal to at least 20% of the length of the minimum leakage path LFₘᵢₙ and/or a height H equal to at least 25% of the minimum leakage path LFₘᵢₙ.

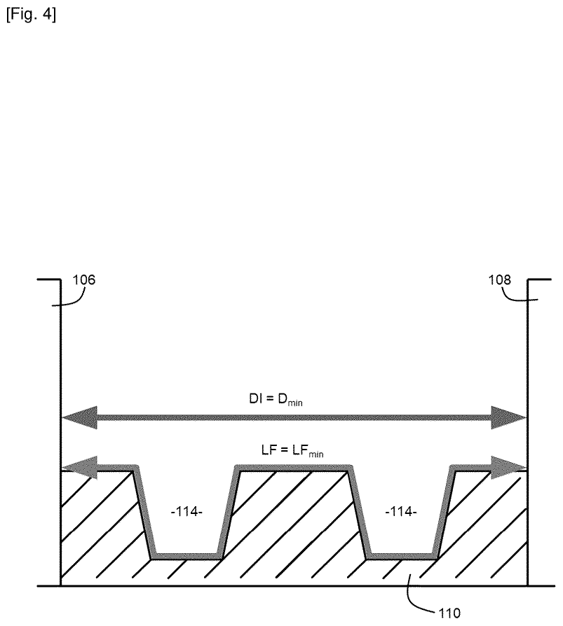

FIG. 4 illustrates the case the grooves 114 are dimensioned so that the length of the leakage path LF is equal to the length of the minimum leakage path LFₘᵢₙ, with the insulation distance DI equal to the minimum insulation distance DIₘᵢₙ. In this case, the electric conductors 106, 108 are as close together as possible to avoid partial discharges, taking into account the aircraft operating conditions used to calculate the minimum insulation distance DIₘᵢₙ and the minimum leakage path LFₘᵢₙ (maximum potential difference, altitude, etc.).

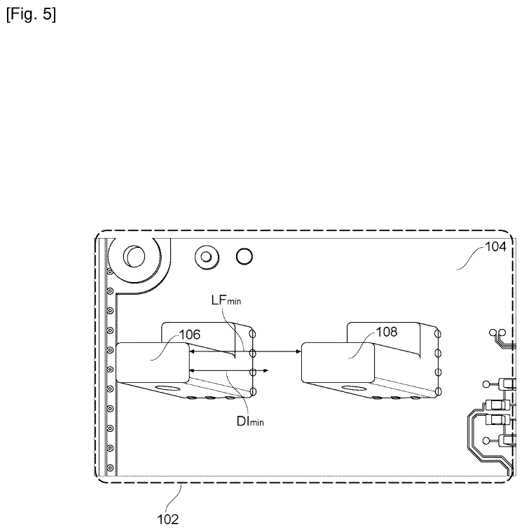

With reference to FIG. 5, in the absence of the spacer 110, the two electric conductors 106, 108 would have to be spaced much further apart to comply with the minimum leakage path LFₘᵢₙ, taken in the example shown to be 1.5 times the minimum insulation distance DIₘᵢₙ.

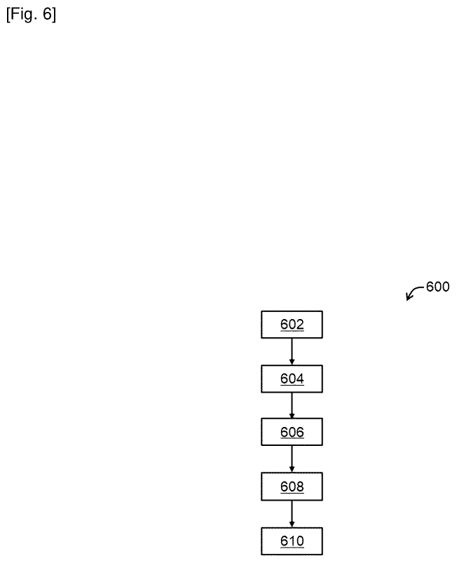

With reference to FIG. 6, a method 600 for manufacturing the electrical system 100 may, for example, comprise the following steps.

In a step 602, the minimum insulation distance DIₘᵢₙ between the two electric conductors 106, 108 is calculated, for example as a function of at least one of: a maximum potential difference between the two electric conductors 106, 108 during operation of the electric circuit 102, at a maximum altitude that the aircraft is designed to reach, at a maximum pollution level that the aircraft is designed to pass through and at the maximum humidity level that the aircraft is designed to pass through.

In a step 604, the electric circuit 102 is obtained, without the spacer 110, with the two electric conductors 106, 108 spaced apart by the insulation distance DI in the air, the latter being greater than or equal to the minimum insulation distance DIₘᵢₙ. For example, in the case where the spacer 110 is intended to replace a previous spacer present between the electric conductors 106, 108, which is for example no longer suitable for a new environment of the electrical system 100, the step 604 may comprise removing this previous spacer.

In a step 606, the length of a minimum leakage path LFₘᵢₙ is calculated from the maximum altitude that the aircraft is designed to reach, for example from the minimum insulation distance DIₘᵢₙ and the coefficient varying with altitude by which the minimum insulation distance DIₘᵢₙ is multiplied to obtain the length of the minimum leakage path LFₘᵢₙ.

In a step 608, the reliefs 112 of the spacer 110 are designed so that the length of the leakage path LF, once the spacer has been added to the electric circuit 102, is greater than or equal to the length of the minimum leakage path LFₘᵢₙ.

In a step 610, the spacer 110 with the previously designed reliefs 112 is added to the electric circuit 102 so as to extend over the flat support 104, between the two electric conductors 106, 108. The leakage path DF between the two electric conductors 106, 108 along the spacer 110 thus passes through the reliefs 112.

It is clear that an electrical system such as the one described above increases the length of the leakage path over a shorter distance in air, which is ultimately equal to the minimum insulation distance.

It will be further noted that the invention is not limited to the embodiments described above. In fact, it will appear to the person skilled in the art that various modifications can be made to the above-described embodiments, in the light of the teaching just disclosed.

For example, the step 606 and/or step 608 could be performed before the step 604.

In the foregoing detailed presentation of the invention, the terms used should not be interpreted as limiting the invention to the embodiments exposed in the present description but should be interpreted to include all equivalents the anticipation of which is within the reach of the person skilled in the art by applying his general knowledge to the implementation of the teaching just disclosed.

1. An electrical system of an electric propulsion unit of an aircraft, wherein the electrical system comprises: an electric circuit comprising an electrically insulating flat support and two electric conductors secured to the flat support, the two electric conductors being configured to have different respective electric potentials during operation of the electric circuit, the two electric conductors being separated from one another by an air insulation distance; and
an electrically insulating spacer extending over the flat support between the two electric conductors and having reliefs defining a leakage path between the two electric conductors along the spacer, wherein the leakage path passes through the reliefs.

2. The electrical system according to claim 1, wherein the spacer is made of at least one of: Polyarylamide, Polyamide 6-6, Polusulfone, and Polyetheretherketone.

3. The electrical system according to claim 1, wherein the reliefs comprise at least one groove.

4. The electrical system according to claim 3, wherein the groove has a rectangular cross-sectional profile.

5. The electrical system according to claim 3, wherein the groove has a trapezoidal cross-sectional profile.

6. The electrical system according to claim 3, wherein the groove has a width equal to at least 20% of a length of a minimum leakage path to avoid partial discharges between the two electric conductors on the spacer.

7. The electrical system according to claim 3, wherein the groove has a height equal to at least 25% of a length of a minimum leakage path to avoid partial discharges between the two electric conductors on the spacer.

8. An electric propulsion unit of an aircraft comprising an electrical system according to any claim 1.

9. An aircraft comprising an electric propulsion unit according to claim 8.

10. A method of manufacturing an electrical system of an electric propulsion unit of an aircraft, the method comprising:
obtaining an electric circuit having an electrically insulating flat support and two electric conductors secured to the flat support, the two electric conductors being designed to have different respective electric potentials in operation of the electric circuit, the two electric conductors being separated from one another by an air insulation distance; and
adding an electrically insulating spacer so as to extend over the flat support between the two electric conductors the spacer having reliefs defining a leakage path between the two electric conductors along the spacer, wherein the leakage path passes through the reliefs.

11. The method according to claim 10, further comprising:
calculating a minimum insulation distance between the two electric conductors as a function of at least one of:
a maximum potential difference between the two electric conductors during operation of the electric circuit, at a maximum altitude that the aircraft is designed to reach; and a maximum level of pollution that the aircraft is designed to pass through and at the maximum level of humidity that the aircraft is designed to pass through, the electric circuit having the two electric conductors spaced apart by the air insulation distance, the latter being greater than or equal to the minimum insulation distance;
calculating a length of a minimum leakage path from the maximum altitude that the aircraft is designed to reach from the minimum insulation distance and a coefficient varying with altitude; and
designing the reliefs of the spacer so that the leakage path has a length greater than or equal to the length of the minimum leakage path.
